(19) United States
(12) Patent Application Publication
(10) Pub. No.: US 2026/0239841 A1
(43) Pub. Date: Aug. 13, 2026

(54) DISPLAY DEVICE AND METHOD FOR MANUFACTURING SAME

(71) Applicant: Sharp Display Technology Corporation, Kameyama City, Mie (JP)

(72) Inventor: Daichi KUMAGAI, Kameyama City, Mie (JP)

(21) Appl. No.: 19/471,826

(22) PCT Filed: Apr. 4, 2023
(86) PCT No.: PCT/JP2023/013930

§ 371 Date: Oct. 2, 2025

(51) Int. Cl. H10K 59/131; H10K 59/12; H10K 59/121

(52) U.S. Cl. CPC H10K 59/131; H10K 59/1201; H10K 59/1213

(57) ABSTRACT

A TFT layer (20a) includes a plurality of TFTs (9ab) along a gate line (14) and at least one lightning conductor element (9da) provided near the TFTs, each of the TFTs (9ab) includes a first semiconductor layer (12ab) formed in an island shape and overlapping at least part of the gate line (14) in a plan view, and each lightning conductor element (9da) includes a second semiconductor layer (12da) formed in an island shape and overlapping at least part of the gate line (14) in a plan view. In a cross-sectional view, an angle (θd) of an end face of the second semiconductor layer (12da) with respect to an upper face of a resin substrate (10) is larger than an angle (θab) of an end face of the first semiconductor layer (12ab) with respect to the upper face of the resin substrate (10).

### TECHNICAL FIELD

The disclosure relates to a display device and a method for manufacturing the same.

### BACKGROUND ART

In recent years, self-luminous organic electroluminescence (hereinafter also referred to as “EL”) display devices using organic EL elements have attracted attention as display devices that can replace liquid crystal display devices. As an organic EL display device, for example, there is proposed a flexible organic EL display device including, on a flexible resin substrate, a thin film transistor (hereinafter also referred to as “TFT”) layer in which a plurality of TFTs for driving an organic EL element of each subpixel constituting a display region.

In an organic EL display device, caused by electrostatic discharge (hereinafter, also referred to as “ESD”) generated during the manufacturing process thereof, ESD damage of a TFT may occur.

In order to suppress the influence of ESD damage, for example, PTL 1 proposes a semiconductor device (organic EL display device) including a protection circuit having two elements, that is, a protection diode constituted of a transistor and a capacitance component added using one gate of a transistor.

### CITATION LIST

### Patent Literature

PTL 1: JP 2013-77816 A

### SUMMARY

### Technical Problem

However, the protection circuit described in PTL 1 mainly functions after completion (after manufacturing) of the organic EL display device, and therefore, the effect of suppressing ESD damage that occurs during the manufacturing process is insufficient. In addition, when a transistor itself constituting the protection circuit is damaged by ESD generated during the manufacturing process of the organic EL display device, there is a concern that leakage may occur between a wiring line to be protected and an unwanted electrode. Further, in a case where a protection circuit is disposed for each scanning line (signal wiring line), a protection circuit configured of simpler elements is required in an organic EL display device with a narrow frame that is provided around a display region and in which an area occupied by the frame region is small.

The disclosure has been made in view of the above circumstances, and an object of the disclosure is to suppress ESD damage of a TFT caused by ESD generated during the manufacturing process of a display device by using a lightning conductor element that can also be introduced into a display device with a narrow frame.

### Solution to Problem

In order to accomplish the above object, a display device according to the disclosure is a display device including a base substrate, and a thin film transistor layer provided on the base substrate and including a semiconductor film, an inorganic insulating film, and a metal film layered in this order. The thin film transistor layer includes a plurality of signal wiring lines formed of the metal film and provided to extend in parallel to each other in one direction, a plurality of thin film transistors provided corresponding to a plurality of subpixels constituting a display region along each of the signal wiring lines, and at least one lightning conductor element provided near the plurality of thin film transistors along each of the signal wiring lines; each of the thin film transistors includes a first semiconductor layer formed of the semiconductor film and provided in an island shape in such a manner as to overlap at least part of each of the signal wiring lines in a plan view; and each of the lightning conductor elements includes a second semiconductor layer formed of the semiconductor film and provided in an island shape in such a manner as to overlap at least part of each of the signal wiring lines in a plan view. In a cross-sectional view, an angle of an end face of the second semiconductor layer with respect to an upper face of the base substrate is larger than an angle of an end face of the first semiconductor layer with respect to the upper face of the base substrate.

A manufacturing method for a display device according to the disclosure is a method for manufacturing a display device including a base substrate, and a thin film transistor layer provided on the base substrate and including a semiconductor film, an inorganic insulating film, and a metal film layered in this order. The thin film transistor layer includes a plurality of signal wiring lines formed of the metal film and provided to extend in parallel to each other in one direction, a plurality of thin film transistors provided corresponding to a plurality of subpixels constituting a display region along each of the signal wiring lines, and at least one lightning conductor element provided near the plurality of thin film transistors along each of the signal wiring lines; each of the thin film transistors includes a first semiconductor layer formed of the semiconductor film and provided in an island shape in such a manner as to overlap at least part of each of the signal wiring lines in a plan view; and each of the lightning conductor elements includes a second semiconductor layer formed of the semiconductor film and provided in an island shape in such a manner as to overlap at least part of each of the signal wiring lines in a plan view. In the method, forming a thin film transistor layer in which the thin film transistor layer is formed on the base substrate includes: forming a semiconductor layer in which the first semiconductor layer and the second semiconductor layer are formed by, after forming the semiconductor film on a substrate surface where a lower layer of the semiconductor film is formed, patterning the semiconductor film; forming an inorganic insulating film in which the inorganic insulating film is formed on the substrate surface where the first semiconductor layer and the second semiconductor layer are formed in such a manner as to cover the first semiconductor layer and the second semiconductor layer; and forming a wiring line layer in which the plurality of signal wiring lines are formed by, after forming the metal film on the substrate surface where the inorganic insulating film is formed, patterning the metal film. In the forming a semiconductor layer, by controlling a photoresist contact angle and/or an etching condition of the semiconductor film, an angle of an end face of the second semiconductor layer with respect to an upper face of the base substrate is made larger than an angle of an end face of the first semiconductor layer with respect to the upper face of the base substrate in a cross-sectional view.

### Advantageous Effects of Disclosure

According to the disclosure, it is possible to suppress ESD damage of a TFT caused by ESD generated during the manufacturing process of a display device by using a lightning conductor element that can also be introduced into a display device with a narrow frame.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an equivalent circuit diagram illustrating a pixel circuit of the organic EL display device according to the first embodiment of the disclosure.

FIG. 5 is a schematic plan view schematically illustrating arrangement of a pixel circuit of the organic EL display device according to the first embodiment of the disclosure.

FIG. 6 is a schematic plan view schematically illustrating arrangement of a pixel circuit and a lightning conductor element of the organic EL display device according to the first embodiment of the disclosure.

FIG. 7 is an enlarged plan view of a portion surrounded by a two-dot chain line in FIG. 6, in which illustrated are a TFT constituting a pixel circuit and a lightning conductor element of the organic EL display device according to the first embodiment of the disclosure.

FIG. 8 is an enlarged cross-sectional view illustrating a TFT constituting a pixel circuit and a lightning conductor element of the organic EL display device according to the first embodiment of the disclosure taken along a line VIII-VIII in FIG. 7.

FIG. 9 is a cross-sectional view illustrating an organic EL layer constituting the organic EL display device according to the first embodiment of the disclosure.

FIG. 10 is a schematic plan view schematically illustrating arrangement of pixel circuits and first and second lightning conductor elements of an organic EL display device according to a second embodiment of the disclosure; the drawing corresponds to FIG. 6.

FIG. 11 is an enlarged plan view of a portion surrounded by a two-dot chain line (a) in FIG. 10, in which illustrated are a TFT constituting a pixel circuit and a first lightning conductor element of the organic EL display device according to the second embodiment of the disclosure; the drawing corresponds to FIG. 7.

FIG. 12 is an enlarged plan view of a portion surrounded by a two-dot chain line (b) in FIG. 10, in which illustrated are TFTs constituting pixel circuits and a second lightning conductor element of the organic EL display device according to the second embodiment of the disclosure; the drawing corresponds to FIG. 7.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

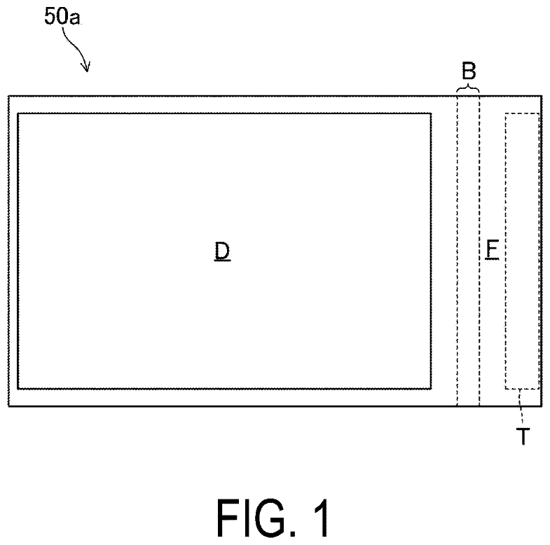

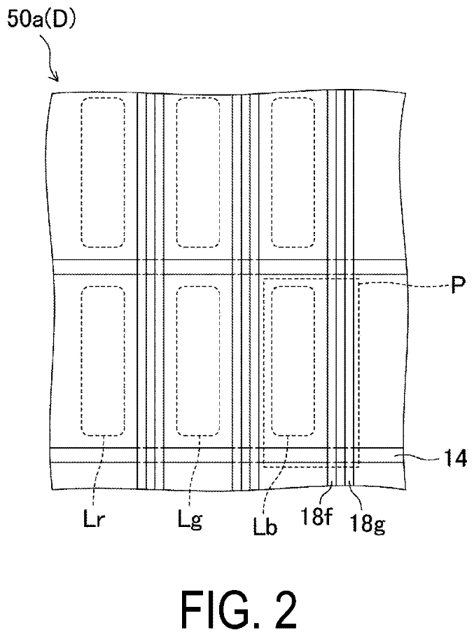

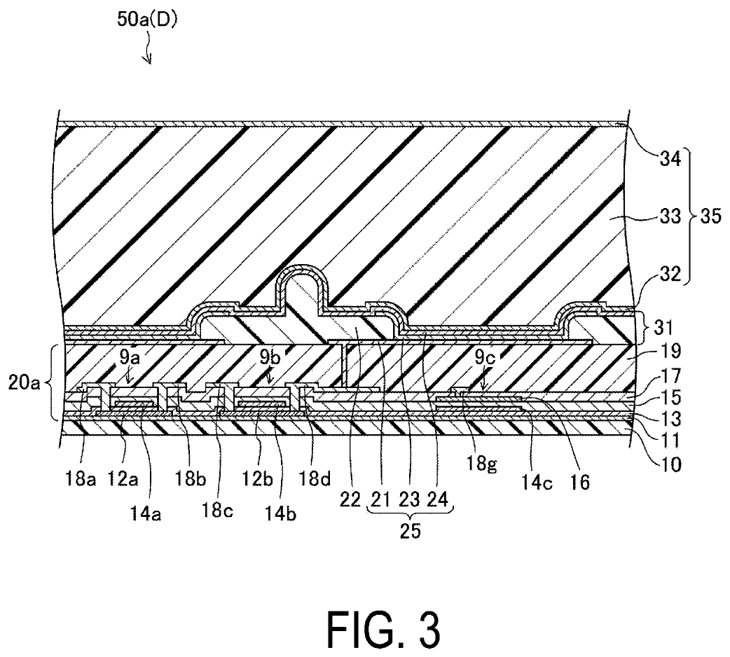

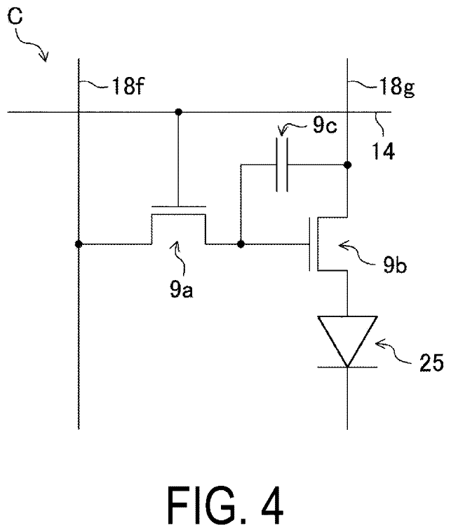

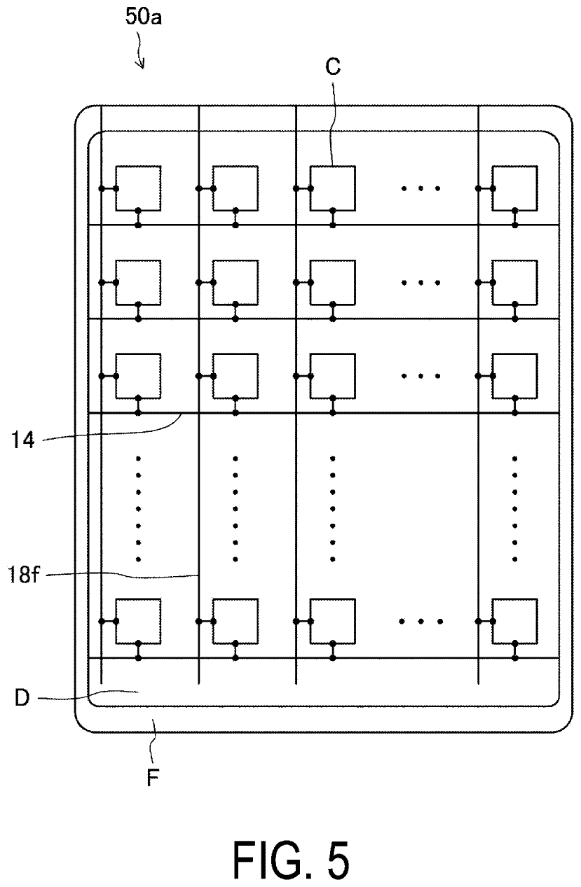

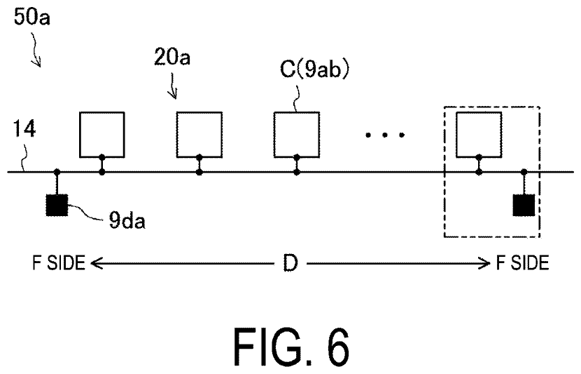

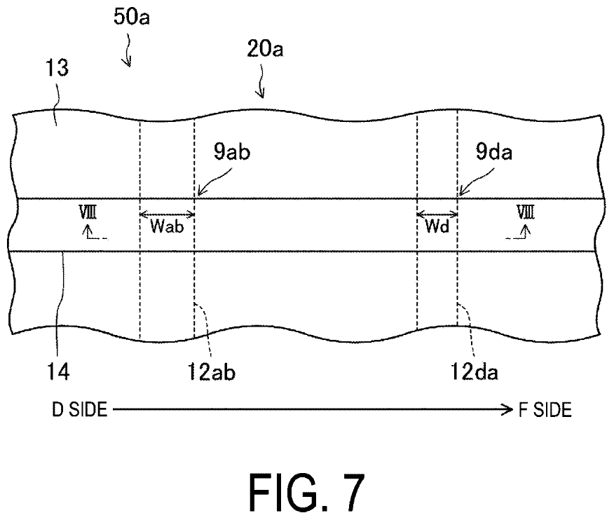

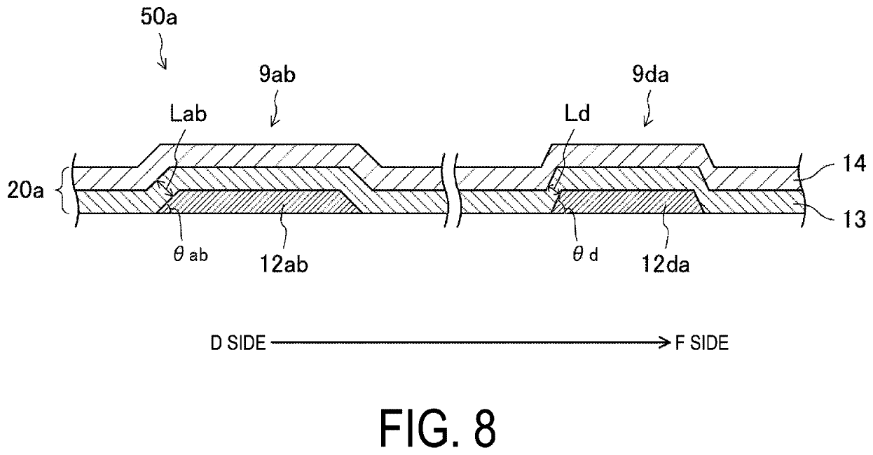

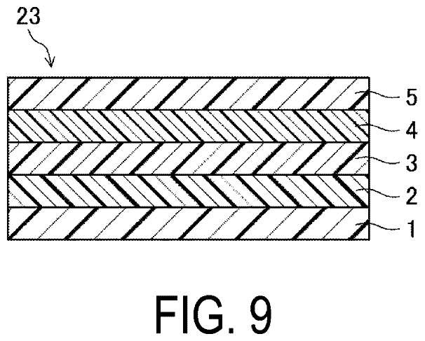

FIG. 1 to FIG. 9 illustrate a first embodiment of a display device according to the disclosure. Further, in each of the following embodiments, an organic EL display device including organic EL elements will be exemplified as a display device including light-emitting elements. Here, FIG. 1 is a plan view illustrating a schematic configuration of an organic EL display device 50a according to the present embodiment. FIG. 2 is a plan view of a display region D of the organic EL display device 50a. FIG. 3 is a cross-sectional view of the display region D of the organic EL display device 50a. FIG. 4 is an equivalent circuit diagram illustrating a pixel circuit C of the organic EL display device 50a. FIG. 5 is a schematic plan view schematically illustrating arrangement of the pixel circuit C of the organic EL display device 50a. FIG. 6 is a schematic plan view schematically illustrating arrangement of the pixel circuit C and a lightning conductor element 9da of the organic EL display device 50a. FIG. 7 is an enlarged plan view of a portion surrounded by a two-dot chain line in FIG. 6, in which illustrated are a TFT 9ab (a first TFT 9a, a second TFT 9b) constituting the pixel circuit C and the lightning conductor element 9da of the organic EL display device 50a. FIG. 8 is an enlarged cross-sectional view illustrating the TFT 9ab constituting the pixel circuit C and the lightning conductor element 9da of the organic EL display device 50a taken along a line VIII-VIII in FIG. 7. FIG. 9 is a cross-sectional view illustrating an organic EL layer 23 constituting the organic EL display device 50a. In FIGS. 7 and 8, an upper layer of a first wiring line layer described below is omitted.

As illustrated in FIG. 1, the organic EL display device 50a includes, for example, a display region D that is provided in a rectangular shape and in which an image is displayed, and a frame region F provided in a frame-like shape around the display region D. Note that, in the present embodiment, the display region D having the rectangular shape is exemplified, but the rectangular shape includes a substantially rectangular shape such as a shape whose sides are arc-shaped, a shape whose corners are arc-shaped, and a shape in which a part of a side has a notch.

As illustrated in FIG. 2, a plurality of subpixels P are arrayed in a matrix shape in the display region D. In the display region D, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another, as illustrated in FIG. 2. Note that one pixel is configured by, for example, three adjacent subpixels P including the red light-emitting region Lr, the green light-emitting region Lg, and the blue light-emitting region Lb in the display region D. The arrangement of the subpixels P is not particularly limited, and examples thereof include a PenTile arrangement and a stripe arrangement.

A terminal portion T is provided at one end portion (a right end portion in FIG. 1) of the frame region F in such a manner as to extend in one direction (a longitudinal direction in FIG. 1). In addition, as illustrated in FIG. 1, in a part of the frame region F between the terminal portion T and the display region D, a bending portion B, which is bendable, for example, by 180 degrees (in a U shape) with the longitudinal direction in FIG. 1 taken as a bending axis, is provided to extend in one direction (the longitudinal direction in FIG. 1).

As illustrated in FIG. 3, the organic EL display device 50a includes a resin substrate 10 provided as a base substrate, and a TFT layer 20a provided on the resin substrate 10.

The resin substrate 10 is made, for example, of an organic resin material such as a polyimide resin or the like.

As illustrated in FIG. 3, the TFT layer 20a includes a base coat film 11 provided on the resin substrate 10, a plurality of first TFTs 9a, a plurality of second TFTs 9b and a plurality of capacitors 9c, which are provided for each subpixel P on the base coat film 11, and a flattening film 19 provided on each first TFT 9a, each second TFT 9b, and each capacitor 9c. In the TFT layer 20a, the base coat film 11, a semiconductor film to serve as semiconductor layers 12a and 12b, a gate insulating film 13 (inorganic insulating film), a first metal film (metal film) to serve as a first wiring line layer such as a gate line 14 (see FIG. 2 and FIGS. 4 to 8), gate electrodes 14a and 14b, and a lower conductive layer 14c, a first interlayer insulating film 15, a second metal film to serve as a second wiring line layer such as an upper conductive layer 16, a second interlayer insulating film 17, a third metal film to serve as a third wiring line layer such as a source line 18f (see FIGS. 2, 4, and 5), source electrodes 18a and 18c, drain electrodes 18b and 18d, and a power source line 18g, and the flattening film 19 are layered on the resin substrate 10 in this order as illustrated in FIG. 3.

Each of the base coat film 11, the gate insulating film 13, the first interlayer insulating film 15, and the second interlayer insulating film 17 is formed of, for example, a single-layer film or a layered film of an inorganic insulating film of silicon nitride (SiNx (x is a positive number)), silicon oxide (SiO₂), silicon oxynitride (SiON), or the like.

The semiconductor film is formed of, for example, a low-temperature polysilicon film of low temperature polysilicon (LTPS), an In-Ga-Zn-O based oxide semiconductor film, or the like. Hereinafter, the first TFT 9a and the second TFT 9b will be described as p-type TFTs, in which the semiconductor layers 12a and 12b (polysilicon semiconductor layers) formed of a polysilicon film as a semiconductor film are doped with impurities such as boron.

Each of the first metal film, the second metal film, and the third metal film is formed of, for example, a metal single layer film of a metal such as molybdenum (Mo), titanium (Ti), aluminum (Al), copper (Cu), or tungsten (W), or a metal layered film such as Mo (upper layer)/Al (intermediate layer)/Mo (lower layer), Ti/Al/Ti, Al (upper layer)/Ti (lower layer), Cu/Mo, or Cu/Ti.

The flattening film 19 has a flat surface in the display region D, and is made of, for example, an organic resin material such as a polyimide resin or an acrylic resin, or a polysiloxane-based spin on glass (SOG) material.

As illustrated in FIGS. 2 and 4 to 8, in the TFT layer 20a, a plurality of the gate lines 14 are provided as signal wiring lines in such a manner as to extend in parallel to each other in a lateral direction in the drawings. In addition, as illustrated in FIGS. 2, 4, and 5, in the TFT layer 20a, a plurality of the source lines 18f are provided as signal wiring lines in such a manner as to extend parallel to each other in a direction intersecting with (orthogonal to) the plurality of gate lines 14, that is, in the longitudinal direction in the drawings. Further, as illustrated in FIGS. 2 to 5, in the TFT layer 20a, a plurality of the power source lines 18g are provided in such a manner as to extend parallel to each other in the longitudinal direction in the drawings. Further, the power source lines 18g are provided adjacent to the source lines 18f, respectively, as illustrated in FIG. 2.

The first TFT 9 a is electrically connected to the corresponding gate line 14 and source line 18f (signal wiring lines) in each of the subpixels P, as illustrated in FIG. 4. In addition, the first TFT 9a includes a semiconductor layer 12a, the gate insulating film 13, a gate electrode 14a, the first interlayer insulating film 15, the second interlayer insulating film 17, and a source electrode 18a and a drain electrode 18b provided in order on the base coat film 11 as illustrated in FIG. 3. Here, the semiconductor layer 12a is provided in an island shape on the base coat film 11 as illustrated in FIG. 3, and has, for example, a channel region, a source region, and a drain region. As illustrated in FIGS. 7 and 8, the semiconductor layer 12a is provided in such a manner as to intersect each gate line 14 and overlap with each gate line 14 at a portion of the intersection (hereinafter also referred to as an “intersection portion”, which is at least part of the gate line 14) in a plan view. The gate insulating film 13 is provided to cover the semiconductor layer 12a as illustrated in FIG. 3. The gate electrode 14a is provided on the gate insulating film 13 to overlap with the channel region of the semiconductor layer 12a as illustrated in FIG. 3. The first interlayer insulating film 15 and the second interlayer insulating film 17 are provided in order to cover the gate electrode 14a, as illustrated in FIG. 3. The source electrode 18a and the drain electrode 18b are provided separate from each other on the second interlayer insulating film 17 as illustrated in FIG. 3. In addition, the source electrode 18a and the drain electrode 18b are electrically connected to the source region and the drain region of the semiconductor layer 12a, respectively, via contact holes formed in the layered film of the gate insulating film 13, the first interlayer insulating film 15, and the second interlayer insulating film 17 as illustrated in FIG. 3. In the source region and the drain region, the plurality of first TFTs 9a are electrically connected to each other via the corresponding gate line 14 and source line 18f.

The second TFT 9b is electrically connected to the corresponding first TFT 9a and power source line 18g in each of the subpixels P as illustrated in FIG. 4. In addition, the second TFT 9b includes the semiconductor layer 12b, the gate insulating film 13, the gate electrode 14b, the first interlayer insulating film 15, the second interlayer insulating film 17, and the source electrode 18c and the drain electrode 18d provided in order on the base coat film 11 as illustrated in FIG. 3. Here, the semiconductor layer 12b is provided in an island shape on the base coat film 11 as illustrated in FIG. 3, and has, for example, a channel region, a source region, and a drain region. As illustrated in FIG. 3, the gate insulating film 13 is provided so as to cover the semiconductor layer 12b. As illustrated in FIG. 3, the gate electrode 14b is provided on the gate insulating film 13 so as to overlap with the channel region of the semiconductor layer 12b. As illustrated in FIG. 3, the first interlayer insulating film 15 and the second interlayer insulating film 17 are provided in order so as to cover the gate electrode 14b. The source electrode 18c and the drain electrode 18d are provided separate from each other on the second interlayer insulating film 17 as illustrated in FIG. 3. In addition, the source electrode 18c and the drain electrode 18d are electrically connected to the source region and the drain region of the semiconductor layer 12b, respectively, via contact holes formed in the layered film of the gate insulating film 13, the first interlayer insulating film 15, and the second interlayer insulating film 17 as illustrated in FIG. 3.

Further, although the top-gate type first TFT 9a and second TFT 9b are exemplified in the present embodiment, the first TFT 9a and the second TFT 9b may be bottom-gate type TFTs.

The capacitor 9c is electrically connected to the corresponding first TFT 9a and power source line 18g in each of the subpixels P as illustrated in FIG. 4. Here, as illustrated in FIG. 3, the capacitor 9c includes a lower conductive layer 14c formed of the same material as and in the same layer as the gate electrodes 14a and 14b, the first interlayer insulating film 15 provided to cover the lower conductive layer 14c, and the upper conductive layer 16 provided on the first interlayer insulating film 15 to overlap with the lower conductive layer 14c. Further, the upper conductive layer 16 is electrically connected to the power source line 18g via a contact hole formed in the second interlayer insulating film 17 as illustrated in FIG. 3.

In the TFT layer 20a, in each subpixel P, the first TFT 9a, the second TFT 9b, and the capacitor 9c are provided as the pixel circuit C, as illustrated in FIG. 4. As illustrated in FIG. 5, a plurality of the pixel circuits C are arrayed in a matrix shape corresponding to the respective subpixels P. Thus, the plurality of pixel circuits C are arranged along a direction in which the gate line 14 as a signal wiring line extends (the lateral direction in FIGS. 5 and 6). Further, the plurality of pixel circuits C are arranged along a direction in which the source line 18f as a signal wiring line extends (the longitudinal direction in FIG. 5). Note that black circles (⋅) depicted in FIGS. 4 to 6 indicate nodes. In the following description, the first TFT 9a and the second TFT 9b are also collectively referred to as “TFT 9ab”. In addition, in the following description, the semiconductor layer 12a and the semiconductor layer 12b are also collectively referred to as “first semiconductor layer 12ab”.

Here, as illustrated in FIGS. 6 to 8, the organic EL display device 50a includes a plurality (two for each gate line 14 in FIG. 6) of the lightning conductor elements 9 da. The lightning conductor elements 9da are formed in the TFT layer 20a. The lightning conductor element 9da is formed to have the same layer structure as the TFT 9ab except that the lightning conductor element 9da includes a second semiconductor layer 12da instead of the first semiconductor layer 12ab constituting the TFT 9ab. Specifically, similar to the first semiconductor layer 12ab, the second semiconductor layer 12da is provided in an island shape on the base coat film 11, and has, for example, a channel region, a source region, and a drain region. As illustrated in FIGS. 7 and 8, the second semiconductor layer 12da is provided to intersect each gate line 14 and overlap with each gate line 14 at the intersection portion thereof (at least part of the gate line 14) in a plan view. The gate insulating film 13 is provided to cover the second semiconductor layer 12da as illustrated in FIG. 8. The second semiconductor layer 12da is formed of the same material and in the same layer as the first semiconductor layer 12ab. That is, the second semiconductor layer 12da may be formed of the above-described polysilicon film or oxide semiconductor film.

Hereinafter, similar to the first semiconductor layer 12ab constituting the TFT 9ab, the second semiconductor layer 12da is described as a polysilicon semiconductor layer formed of a polysilicon film as a semiconductor film.

As illustrated in FIG. 6, the lightning conductor elements 9da are provided along each of the gate lines 14 in the vicinity of a plurality of the TFTs 9ab. To be specific, the lightning conductor element 9da is arranged on the outer side in the extending direction of the gate line 14 relative to the TFT 9ab arranged at least at one end portion of each gate line 14. In other words, the lightning conductor elements 9da are each arranged along each gate line 14 on a frame region F side relative to each distal-end pixel circuit C (the distal-end TFT 9ab constituting the distal-end pixel circuit C) arranged at a distal end (the distal end on each side in FIG. 6) of the gate line 14 in the display region D. The lightning conductor elements 9da may each be disposed in the display region D (at an end portion on the frame region F side of the display region D) or disposed in the frame region F.

In the organic EL display device 50a, as illustrated in FIG. 7, at an intersection portion between the first semiconductor layer 12ab or second semiconductor layer 12da and the gate line 14, a second width Wd as a width of the second semiconductor layer 12da at the intersection portion with the gate line 14 (the portion intersecting the signal wiring line) is smaller than a first width Wab as a width of the first semiconductor layer 12ab at the intersection portion with the gate line 14 (the portion intersecting the signal wiring line) (Wd<Wab). Thus, as illustrated in FIG. 8, in a cross-sectional view, an angle θd of an end face of the second semiconductor layer 12da with respect to an upper face of the resin substrate 10 is larger than an angle θab of an end face of the first semiconductor layer 12ab with respect to the upper face of the resin substrate 10 (θd>θab). Here, the end face of the first semiconductor layer 12ab and the end face of the second semiconductor layer 12da refer to etched end faces after patterning in a semiconductor layer forming step described below, and are tapered (in the following description, a portion indicating the above end face is also referred to as a “tapered portion”). In the organic EL display device 50a, the tapered portion refers to an end portion in the direction in which the gate line 14 extends. The angle θab of the end face of the first semiconductor layer 12ab and the angle θd of the end face of the second semiconductor layer 12da correspond to a photoresist contact angle of the semiconductor film in the semiconductor layer forming step (in the following description, the above angles are also referred to as “taper angles”). As described above, the taper angle θd of the second semiconductor layer 12da constituting the lightning conductor element 9da is steeper than the taper angle θab of the first semiconductor layer 12ab constituting the TFT 9ab. As a result, as illustrated in FIG. 8, a second distance Ld as a distance between the end face of the second semiconductor layer 12da and a lower face of the gate line 14 (signal wiring line) corresponding thereto is shorter than a first distance Lab as a distance between the end face of the first semiconductor layer 12ab and the lower face of the gate line 14 (signal wiring line) corresponding thereto (Ld<Lab). That is, the gate insulating film 13 at the tapered portion of the lightning conductor element 9da is thinner than the gate insulating film 13 at the tapered portion of the TFT 9ab. Thus, the lightning conductor element 9da becomes a low breakdown-voltage portion having a lower breakdown voltage than the TFT 9ab.

In a known organic EL display device, particularly in the manufacture of an organic EL element (an organic EL element layer forming step to be described below), the manufacturing yield is lowered due to ESD damage of a TFT arranged in the vicinity of a gate line distal end. The following can be considered as the reason for the occurrence of the ESD damage: electric charge that is charged on the gate line during the manufacturing process is stuck at the end portion of the gate line and affects the TFT constituting the pixel circuit in the vicinity thereof. In particular, when the TFT is constituted by a polysilicon semiconductor layer formed of a polysilicon film, an inorganic insulating film, and a gate line, it has been found that ESD damage is likely to occur at a portion where the thickness of the inorganic insulating film corresponding to the tapered portion of the polysilicon semiconductor layer is small.

In contrast, in the organic EL display device 50a of the present embodiment, the lightning conductor element 9da having a lower breakdown voltage than the TFT 9ab is provided on the outer side (on the frame region F side) relative to the TFT 9ab constituting each of the pixel circuits C arranged at the distal ends on both sides of the gate line 14, so that the ESD generated during the manufacturing process is guided to the lightning conductor element 9da. In this manner, the lightning conductor element 9da is expected to function as a protection element (dummy element) for the TFT 9ab (particularly, the first TFT 9a) arranged at the distal end of the gate line 14 and being likely to be affected by ESD. Even when ESD occurs during the manufacturing process, the ESD hardly affects the TFT 9ab due to the presence of the lightning conductor element 9da.

The organic EL display device 50a includes, as an upper layer of the TFT layer 20a, an organic EL element layer 31 provided as a light-emitting element layer constituting the display region D and a sealing film 35 provided on the organic EL element layer 31, as illustrated in FIG. 3.

As illustrated in FIG. 3, the organic EL element layer 31 includes a plurality of organic EL elements 25 as a plurality of light-emitting elements arrayed in a matrix shape corresponding to the plurality of subpixels P.

As illustrated in FIG. 3, the organic EL elements 25 include a plurality of first electrodes 21, a plurality of organic EL layers 23 provided in each of the subpixels P on the first electrodes 21, and a second electrode 24 provided in common to the plurality of subpixels P on the organic EL layer 23, which are provided in sequence on the flattening film 19. As illustrated in FIG. 3, the organic EL element 25 is covered with the sealing film 35.

The first electrodes 21 are provided in a matrix shape on the flattening film 19 to correspond to the plurality of subpixels P as illustrated in FIG. 3. As illustrated in FIG. 3, each of the first electrodes 21 is electrically connected to the drain electrode 18d (or the source electrode 18c) of the corresponding second TFT 9b via a contact hole formed in the flattening film 19. In addition, the first electrode 21 has a function of injecting holes (positive holes) into the organic EL layer 23. In addition, the first electrode 21 is preferably formed of a material having a high work function to improve the efficiency in injection of holes into the organic EL layer 23. Here, examples of a material constituting the first electrode 21 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). In addition, examples of the material constituting the first electrode 21 may include alloys such as astatine (At)/astatine oxide (AtO₂). Furthermore, the material constituting the first electrode 21 may be an electrically conductive oxide such as tin oxide (SnO), zinc oxide (ZnO), indium tin oxide (ITO), or indium zinc oxide (IZO). In addition, the first electrode 21 may be formed by layering a plurality of layers formed of any of the materials described above. Note that examples of compound materials having a high work function include indium tin oxide (ITO) and indium zinc oxide (IZO).

A peripheral edge portion of the first electrode 21 is covered with an edge cover 22 provided in a lattice pattern commonly to the plurality of subpixels P. Here, examples of a material constituting the edge cover 22 include a positive photosensitive resin such as a polyimide resin, an acrylic resin, a polysiloxane resin, and a novolac resin or an SOG material such as polysiloxane. Further, as illustrated in FIG. 3, part of a surface of the edge cover 22 projects upward in the drawing and is a pixel photo spacer provided in an island shape.

The organic EL layers 23 are disposed on each of the first electrodes 21, and are provided in a matrix shape to correspond to the plurality of subpixels P, as illustrated in FIG. 3. Here, as illustrated in FIG. 9, each of the organic EL layers 23 includes a hole injection layer 1, a hole transport layer 2, a light-emitting layer 3, an electron transport layer 4, and an electron injection layer 5, which are provided in this order on the first electrode 21.

The hole injection layer 1 is also called an anode electrode buffer layer, and has a function of reducing an energy level difference between the first electrode 21 and the organic EL layer 23 to thereby improve the efficiency in injection of holes into the organic EL layer 23 from the first electrode 21. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function of improving the efficiency in hole transport from the first electrode 21 to the organic EL layer 23. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 21 and the second electrode 24, respectively, and the holes and the electrons recombine when a voltage is applied via the first electrode 21 and the second electrode 24. Here, the light-emitting layer 3 is made of a material having high luminous efficiency. In addition, examples of the material constituting the light-emitting layer 3 include metal oxinoid compounds [8-hydroxyquinoline metal complexes], naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 has a function of reducing an energy level difference between the second electrode 24 and the organic EL layer 23 and improving the efficiency in electron injection into the organic EL layer 23 from the second electrode 24, and this function lowers the drive voltage of the organic EL element 25. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 24 is provided to cover the organic EL layers 23 and the edge cover 22. In addition, the second electrode 24 has a function of injecting electrons into the organic EL layer 23. In addition, it is more preferable that the second electrode 24 be formed of a material having a low work function to improve the efficiency in electron injection into the organic EL layer 23. Here, examples of the material constituting the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). In addition, the second electrode 24 may also be formed of an alloy of, for example, magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al). In addition, the second electrode 24 may be formed of an electrically conductive oxide, for example, tin oxide (SnO), zinc oxide (ZnO), indium tin oxide (ITO), or indium zinc oxide (IZO). In addition, the second electrode 24 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 3, the sealing film 35 includes a first sealing inorganic insulating film 32 provided to cover the second electrode 24, a sealing organic film 33 provided on the first sealing inorganic insulating film 32, and a second sealing inorganic insulating film 34 provided to cover the sealing organic film 33, and has a function of protecting the organic EL layer 23 from moisture, oxygen, and the like. Here, the first sealing inorganic insulating film 32 and the second sealing inorganic insulating film 34 are each formed of, for example, an inorganic material such as silicon oxide (SiO₂), aluminum oxide (Al₂O₃), silicon nitride (SiNx (x is a positive number)) such as trisilicon tetranitride (Si₃N₄), and silicon carbonitride (SiCN). Further, the sealing organic film 33 is formed of, for example, an organic material such as an acrylic resin, a polyurea resin, a parylene resin, a polyimide resin, and a polyamide resin.

In the organic EL display device 50a described above, in each subpixel P, a gate signal is input to the first TFT 9a via the gate line 14 to turn on the first TFT 9a, a data signal is written in the gate electrode 14b of the second TFT 9b and the capacitor 9c via the source line 18f, and a current from the power source line 18g corresponding to the gate voltage of the second TFT 9b is supplied to the organic EL layer 23, whereby the light-emitting layer 3 of the organic EL layer 23 emits light to display an image. Further, in the organic EL display device 50a, even when the first TFT 9a is turned off, the gate voltage of the second TFT 9b is held by the capacitor 9c, and thus, light emission by the light-emitting layer 3 is maintained until a gate signal of the next frame is input.

Next, a method for manufacturing the organic EL display device 50a according to the present embodiment will be described. The method for manufacturing the organic EL display device 50a according to the present embodiment includes a TFT layer forming step.

### TFT Layer Forming Step

The TFT layer forming step is a step of forming the TFT layer 20a on the resin substrate 10. For example, on the surface of the resin substrate 10 formed on a glass substrate, the base coat film 11, the first TFTs 9a, the second TFTs 9b, the capacitors 9c, the flattening film 19, and the like are formed by using a known method. In this case, the TFT layer forming step of the present embodiment includes a semiconductor layer forming step, an insulating film forming step, and a wiring line layer forming step.

### Semiconductor Layer Forming Step

An amorphous silicon film (having a thickness of about 50 nm) is formed, for example, by plasma chemical vapor deposition (CVD) on the substrate surface on which the base coat film 11 is formed as a layer below the semiconductor layer, the amorphous silicon film is crystallized by laser annealing or the like to form a polysilicon film made of polysilicon, and then the polysilicon film is patterned to form the island-shaped first semiconductor layer 12ab and the island-shaped second semiconductor layer 12da. A plurality of the first semiconductor layers 12ab are arranged in the display region D along the gate lines 14 formed in the subsequent wiring line layer forming step. The second semiconductor layer 12da is arranged on the outer side (on the frame region F side) along the gate line 14 relative to the first semiconductor layer 12ab arranged at the distal end on each side of the gate line 14.

In the method for manufacturing the organic EL display device 50a, in the semiconductor layer forming step, the taper angle θd of the second semiconductor layer 12da is formed to be larger than the taper angle θab of the first semiconductor layer 12ab in a cross-sectional view by controlling one or both of the photoresist contact angle and an etching condition of the semiconductor film. For example, to satisfy the relation of θd>θab, a method of intentionally steepening the photoresist contact angle, a method of intentionally causing the angle of the etched end face of the semiconductor film to differ in height by using a graytone mask for exposure with respect to the semiconductor film, and the like can be cited. As described above, the lightning conductor element 9da, which serves as a protection element for the first TFT 9a and the second TFT 9b, having a lower breakdown voltage than these TFTs can be formed by being subjected to the subsequent steps without adding a step or a mask.

### Insulating Film Forming Step

After forming a silicon oxide film (having a thickness of about 100 nm) by, for example, plasma CVD on the substrate surface on which the first semiconductor layer 12ab and the second semiconductor layer 12da are formed, the silicon oxide film is patterned in such a manner as to cover the first semiconductor layer 12ab and the second semiconductor layer 12da, thereby forming the gate insulating film 13 (inorganic insulating film).

### Wiring Line Layer Forming Step

After forming the first metal film (metal film) such as a molybdenum film (having a thickness of about 200 nm) by, for example, sputtering on the substrate surface on which the gate insulating film 13 is formed, the first metal film is patterned to form the first wiring line layer such as the gate electrode 14a, the gate line 14, and the like.

The method for manufacturing the organic EL display device 50a includes an organic EL element layer forming step and a sealing film forming step.

### Organic EL Element Layer Forming Step

On the flattening film 19 of the TFT layer 20a formed in the TFT layer forming step, the first electrode 21, the edge cover 22, the organic EL layer 23 (the hole injection layer 1, the hole transport layer 2, the light-emitting layer 3, the electron transport layer 4, and the electron injection layer 5), and the second electrode 24 are formed using a known method, thereby forming the organic EL element 25 and forming the organic EL element layer 31.

### Sealing Film Forming Step

First, an inorganic insulating film such as a silicon nitride film, a silicon oxide film, or a silicon oxynitride film is formed by plasma CVD using a CMM as a vapor deposition mask on the substrate surface on which the organic EL element layer 31 having been formed in the organic EL element layer forming step is formed in such a manner as to cover each of the organic EL elements 25, thereby forming the first sealing inorganic insulating film 32. Subsequently, an organic resin material such as an acrylic resin is film-formed on the first sealing inorganic insulating film 32 by, for example, an ink-jet method, thereby forming the sealing organic film 33. Thereafter, the second sealing inorganic insulating film 34 is formed by forming an inorganic insulating film such as a silicon nitride film, a silicon oxide film, or a silicon oxynitride film by plasma CVD using a CMM as a vapor deposition mask in such a manner as to cover the sealing organic film 33, thereby forming the sealing film 35. Through the above steps, the sealing film 35, in which the first sealing inorganic insulating film 32, the sealing organic film 33, and the second sealing inorganic insulating film 34 are sequentially layered, can be formed in the display region D.

Finally, after a protective sheet (not illustrated) is applied to the substrate surface, the glass substrate is peeled off from the lower face of the resin substrate 10 by irradiation with laser light from the glass substrate side of the resin substrate 10, and then a protective sheet (not illustrated) is applied to the lower face of the resin substrate 10, from which the glass substrate has been peeled off. As discussed above, the organic EL display device 50a can be manufactured.

### Effects

As described above, with the organic EL display device 50a and the method for manufacturing the same according to the present embodiment, the following effects can be obtained.

The organic EL display device 50a includes, in the TFT layer 20a, the lightning conductor elements 9da on the outer side (on the frame region F side) relative to the TFTs 9ab arranged at distal ends on both sides of the gate line 14 among the plurality of TFTs 9ab provided in the display region D along the direction in which the gate line 14 extends; the lightning conductor element 9da has the same layer structure as the TFT 9ab except that the lightning conductor element 9da is constituted by the second semiconductor layer 12da in place of the first semiconductor layer 12ab constituting the TFT 9ab. Then, the taper angle θd of the second semiconductor layer 12da is larger than the taper angle θab of the first semiconductor layer 12ab (θd>θab). Thus, as illustrated in FIG. 8, at the tapered portion, the second distance Ld as a distance between the end face of the second semiconductor layer 12da and the lower face of the gate line 14 (signal wiring line) corresponding thereto (i.e., the thickness of the gate insulating film 13) is shorter than the first distance Lab as a distance between the end face of the first semiconductor layer 12ab and the lower face of the gate line 14 (signal wiring line) corresponding thereto (Ld<Lab), whereby the lightning conductor element 9da becomes a low breakdown-voltage portion having a lower breakdown voltage than the TFT 9ab. As a result, the electric charge charged on the gate line 14 during the manufacturing process of the display device is guided to the lightning conductor element 9da, so that the ESD damage of the TFT 9ab (particularly, the first TFT 9a) caused by the ESD generated during the manufacturing process can be suppressed.

Further, as illustrated in FIG. 7, the lightning conductor element 9da serving as a protection element for the TFT 9ab is provided along the same gate line 14; at the intersection portions with the gate line 14, the second width Wd as a width of the second semiconductor layer 12da at the intersection portion with the gate line 14 (the portion intersecting the signal wiring line) is smaller than the first width Wab as a width of the first semiconductor layer 12ab at the intersection portion with the gate line 14 (the portion intersecting the signal wiring line) (Wd<Wab), whereby the lightning conductor element 9da can be a simple element that does not become a large obstacle when the frame is narrowed, and can be introduced into the organic EL display device 50a with a narrow frame.

In the method for manufacturing the organic EL display device 50a, in the TFT layer forming step (the semiconductor layer forming step thereof) similar to a known step, it is only necessary to intentionally provide a difference in height of the taper angle to satisfy the relation of θd>θab by controlling the photoresist contact angle and/or the etching condition of the semiconductor film, and an additional step, mask, or the like is not required. Therefore, a typically known process is adopted as a method for manufacturing the organic EL display device 50a, which is also excellent in workability.

### Second Embodiment

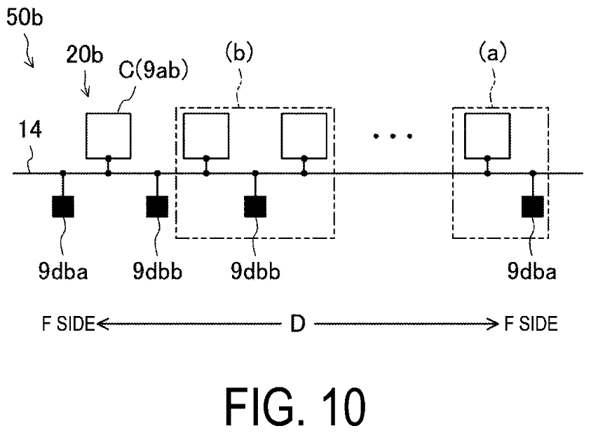

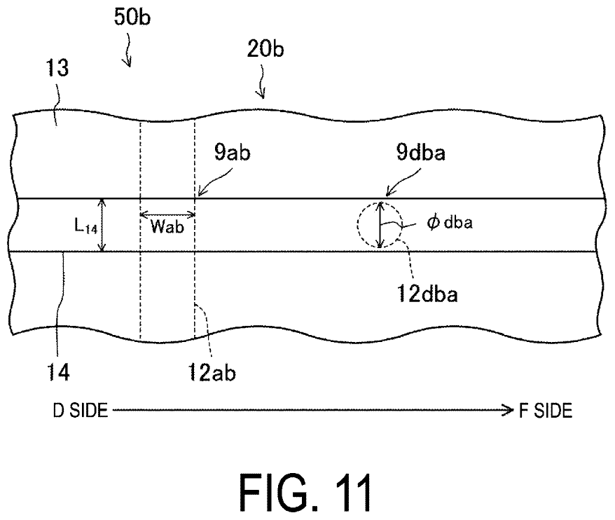

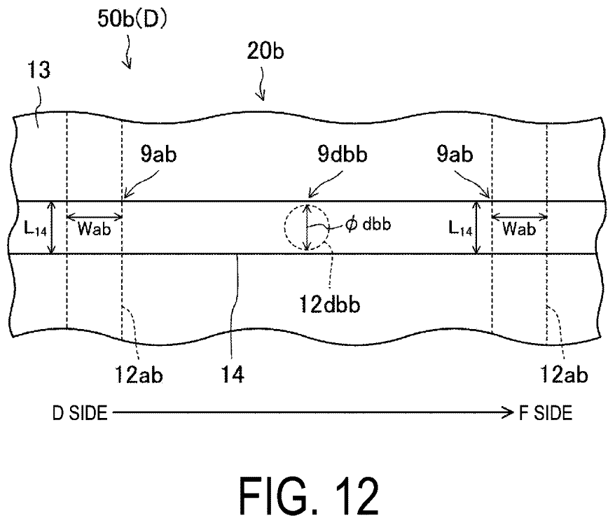

Next, a second embodiment of the disclosure will be described with reference to FIGS. 10 to 12. FIG. 10 is a schematic plan view schematically illustrating arrangement of pixel circuits C and first and second lightning conductor elements 9dba and 9dbb of an organic EL display device 50b according to the present embodiment; the drawing corresponds to FIG. 6. FIG. 11 is an enlarged plan view of a portion surrounded by a two-dot chain line (a) in FIG. 10, in which illustrated are a TFT 9ab constituting the pixel circuit C and the first lightning conductor element 9dba of the organic EL display device 50b; the drawing corresponds to FIG. 7. FIG. 12 is an enlarged plan view of a portion surrounded by a two-dot chain line (b) in FIG. 10, in which illustrated are TFTs 9ab constituting the pixel circuit C and the second lightning conductor element 9dbb of the organic EL display device 50b; the drawing corresponds to FIG. 7. The overall configuration of the organic EL display device 50b is the same as that of the first embodiment described above other than the configuration of a TFT layer 20b, and therefore detailed description thereof will be omitted. Note that constituent portions similar to those in the first embodiment described above are denoted by the identical reference signs, and description thereof will be omitted. In FIGS. 11 and 12, an upper layer of a first wiring line layer is omitted.

As illustrated in FIGS. 10 to 12, in the organic EL display device 50b, the TFT layer 20b includes a plurality (two for each gate line 14 in FIG. 10) of the first lightning conductor elements 9dba and a plurality of the second lightning conductor elements 9dbb.

The first lightning conductor element 9dba corresponds to the lightning conductor element 9da included in the organic EL display device 50a (the TFT layer 20a thereof). As illustrated in FIG. 10, similar to the lightning conductor elements 9da, the first lightning conductor elements 9dba are each arranged along each gate line 14 on the frame region F side relative to each distal-end pixel circuit C (the distal-end TFT 9ab constituting the distal-end pixel circuit C) arranged at a distal end (the distal end on each side in FIG. 10) of the gate line 14 in the display region D. The first lightning conductor element 9dba may be disposed in the display region D (at an end portion on the frame region F side of the display region D) or may be disposed in the frame region F.

On the other hand, as illustrated in FIG. 11, the planar shape and size of a second semiconductor layer 12dba formed in an island shape and constituting the first lightning conductor element 9dba are different from those of the island-shaped second semiconductor layer 12da constituting the lightning conductor element 9da. Specifically, the second semiconductor layer 12dba is provided in a circular shape. The planar shape of the second semiconductor layer 12dba is not limited to a circular shape, and may be, for example, a trapezoidal shape or a rectangular shape. The size of the circular second semiconductor layer 12dba (diameter φdba in FIG. 11) is smaller than the first width Wab as the width of the first semiconductor layer 12ab constituting the TFT 9ab at the intersection portion with the gate line 14 (the portion intersecting the signal wiring line) and a width L14 of the gate line 14 (φdba<Wab and φdba<L14). That is, the second semiconductor layer 12dba is provided so that the entirety thereof overlaps the gate line 14 in a plan view.

The second lightning conductor element 9dbb is configured to have a structure and a shape similar to those of the first lightning conductor element 9dba. That is, as illustrated in FIG. 12, a second semiconductor layer 12dbb constituting the second lightning conductor element 9dbb is provided in a circular shape, similar to the second semiconductor layer 12dba constituting the first lightning conductor element 9dba. Similarly to the second semiconductor layer 12dba, the size of the circular second semiconductor layer 12dbb (diameter φdbb in FIG. 12) is smaller than the first width Wab as the width of the first semiconductor layer 12ab at the intersection portion with the gate line 14 (the portion intersecting the signal wiring line) and the width L14 of the gate line 14 (φdbb<Wab and φdbb<L14).

On the other hand, as illustrated in FIGS. 10 and 12, the second lightning conductor element 9dbb is arranged between the plurality of TFTs 9ab adjacent to each other, unlike the lightning conductor element 9da and the first lightning conductor element 9dba. That is, the second lightning conductor element 9dbb is provided between the adjacent pixel circuits C in the display region D.

The taper angle θd of the second semiconductor layer 12dba constituting the first lightning conductor element 9dba and of the second semiconductor layer 12dbb constituting the second lightning conductor element 9dbb is larger than the taper angle θab of the first semiconductor layer 12ab constituting the TFT 9ab (θd>θab), similarly to the second semiconductor layer 12da constituting the lightning conductor element 9da. Further, at the tapered portion, the second distance Ld as the distance between the end face of the second semiconductor layer 12dba or second semiconductor layer 12dbb and the lower face of the gate line 14 (signal wiring line) corresponding thereto (i.e., the thickness of the gate insulating film 13) is shorter than the first distance Lab as the distance between the end face of the first semiconductor layer 12ab and the gate line 14 (signal wiring line) corresponding thereto (Ld<Lab).

In the present embodiment, although the organic EL display device 50b including the first lightning conductor element 9dba and the second lightning conductor element 9dbb is exemplified, the disclosure is not limited thereto, and the organic EL display device may include only the second lightning conductor element 9dbb. However, from the viewpoint of further suppressing ESD damage of the TFT 9ab (particularly, the first TFT 9a) caused by the ESD generated during the manufacturing process, it is preferable to include both the first lightning conductor element 9dba and the second lightning conductor element 9dbb.

For example, an organic EL display device in which the first embodiment and the second embodiment are combined may be provided. For example, the organic EL display device may include the lightning conductor element 9da exemplified in the first embodiment and the second lightning conductor element 9dbb exemplified in the second embodiment.

In the organic EL display device 50b, the second semiconductor layer 12dba and the second semiconductor layer 12dbb are required to be formed by changing the pattern shape of the semiconductor film in the semiconductor layer forming step of the TFT layer forming step of the organic EL display device 50a discussed above.

### Effects

According to the organic EL display device 50b described above, the following effects can be obtained in addition to the effects of the above-described organic EL display device 50a.

The organic EL display device 50b includes in the TFT layer 20a, in addition to the first lightning conductor element 9dba corresponding to the lightning conductor element 9da included in the organic EL display device 50a, the second lightning conductor element 9dbb arranged between the plurality of TFTs 9ab provided in the display region D along the direction in which the gate line 14 extends. That is, in the organic EL display device 50b, the protection elements for the TFTs 9ab are arranged on the outer side (on the frame region F side) in the direction in which the gate line 14 extends relative to the TFTs 9ab arranged at the distal ends on both sides of each gate line 14, and also arranged between the TFTs 9ab adjacent to each other. Thus, the electric charge charged on the gate line 14 during the manufacturing process of the display device is guided to these two first and second lightning conductor elements 9dba and 9dbb, so that the ESD damage of the TFT 9ab (particularly, the first TFT 9a) caused by the ESD generated during the manufacturing process can be further suppressed.

Further, as illustrated in FIGS. 11 and 12, the sizes (diameters φdba, φdbb) of the two first and second lightning conductor elements 9dba and 9dbb are smaller than the first width Wab as the width of the first semiconductor layer 12ab constituting the TFT 9ab at the intersection portion with the gate line 14 (the portion intersecting the signal wiring line) and the width L14 of the gate line 14 (φdba<Wab and φdba<L14, φdbb<Wab and φdbb <L14).

Accordingly, even when, in addition to providing the first lightning conductor element 9dba on the outer side of the TFT 9ab at the distal end of the gate line 14, the second lightning conductor element 9dbb is provided between the TFTs 9ab, the pattern density of the semiconductor layer (second semiconductor layer 12dba, 12dbb) is not largely increased. Therefore, the two first and second lightning conductor elements 9dba and 9dbb can be simple elements that do not become large obstacles when the frame is narrowed, and can be introduced into the organic EL display device 50b with a narrow frame.

### Other Embodiments

In each of the above embodiments, the TFT layer including the plurality of lightning conductor elements along each gate line is exemplified, but the disclosure is not limited thereto, and the TFT layer may include at least one lightning conductor element along each gate line.

In each of the above embodiments, the TFT layer in which the lightning conductor elements are arranged at the distal ends on both sides of each gate line is exemplified, but the disclosure is not limited thereto, and the TFT layer in which the lightning conductor element is arranged at a distal end on one side (at least at one end portion) of each gate line may be used.

In each of the above embodiments, the gate line (first wiring line layer) is exemplified as the signal wiring line, but the disclosure is not limited thereto, and the signal wiring line may be the source line (second wiring line layer), the power source line (third wiring line layer), or the like.

In each of the above embodiments, the inorganic layered film is configured of four layers in which the gate insulating film, the first interlayer insulating film, and the second interlayer insulating film are layered in this order on the base coat film, but the inorganic layered film may be configured of a single layer of the base coat film, or may be configured of two layers of the base coat film and the gate insulating film.

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

In each of the embodiments described above, the organic EL display device in which the electrode of the TFT connected to the first electrode serves as the drain electrode is exemplified. However, the disclosure is also applicable to an organic EL display device in which the electrode of the TFT connected to the first electrode is referred to as the source electrode.

Although the organic EL display device is exemplified as a display device in each of the embodiments described above, the disclosure is also applicable to a display device such as a liquid crystal display device employing an active matrix driving method.

In each of the embodiments described above, the organic EL display device is exemplified and described as the display device, but the disclosure is not limited to the organic EL display device and is also applicable to any flexible display device. For example, the disclosure is applicable to a flexible display device including quantum-dot light-emitting diodes (QLEDs), which are light-emitting elements using a quantum dot-containing layer, or the like.

### INDUSTRIAL APPLICABILITY

As described above, the disclosure is useful for a flexible display device.

1. A display device comprising:
a base substrate; and
a thin film transistor layer provided on the base substrate and including a semiconductor film, an inorganic insulating film, and a metal film layered in this order, the thin film transistor layer including
a plurality of signal wiring lines formed of the metal film and provided to extend in parallel to each other in one direction,
a plurality of thin film transistors provided corresponding to a plurality of subpixels constituting a display region along each of the signal wiring lines, and
at least one lightning conductor element provided near the plurality of thin film transistors along each of the signal wiring lines, each of the thin film transistors including
a first semiconductor layer formed of the semiconductor film and provided in an island shape in such a manner as to overlap at least part of each of the signal wiring lines in a plan view, each of the lightning conductor elements including
a second semiconductor layer formed of the semiconductor film and provided in an island shape in such a manner as to overlap at least part of each of the signal wiring lines in a plan view,
wherein in a cross-sectional view, an angle of an end face of the second semiconductor layer with respect to an upper face of the base substrate is larger than an angle of an end face of the first semiconductor layer with respect to the upper face of the base substrate.

2. The display device according to claim 1,
wherein a distance between an end face of the second semiconductor layer and a lower face of the signal wiring line corresponding to the end face of the second semiconductor layer is shorter than a distance between an end face of the first semiconductor layer and the lower face of the signal wiring line corresponding to the end face of the first semiconductor layer.

3. The display device according to claim 1 or 2,
wherein the first semiconductor layer and the second semiconductor layer respectively intersect with the signal wiring lines, and
a width of a portion of the second semiconductor layer intersecting with each of the signal wiring lines is smaller than a width of a portion of the first semiconductor layer intersecting with each of the signal wiring lines.

4. The display device according to claim 1 or 2,
wherein the first semiconductor layer intersects with each of the signal wiring lines, and
the second semiconductor layer is smaller than a width of a portion of the first semiconductor layer intersecting with each of the signal wiring lines and a width of each of the signal wiring lines.

5. The display device according to any one of claims 1 to 4,
wherein the at least one lightning conductor element is arranged on an outer side in a direction in which each of the signal wiring lines extends relative to the thin film transistor arranged at least at one end portion of each of the signal wiring lines.

6. The display device according to any one of claims 1 to 4,
wherein the at least one lightning conductor element is arranged between the plurality of thin film transistors adjacent to each other.

7. The display device according to any one of claims 1 to 4,
wherein a plurality of the lightning conductor elements are provided, and
the plurality of lightning conductor elements are arranged on an outer side in a direction in which each of the signal wiring lines extends relative to the thin film transistor arranged at least at one end portion of each of the signal wiring lines, and also arranged between the plurality of thin film transistors adjacent to each other.

8. The display device according to any one of claims 1 to 7,
wherein the first semiconductor layer and the second semiconductor layer are each formed of a polysilicon film.

9. The display device according to any one of claims 1 to 8,
wherein the signal wiring lines are gate lines.

10. The display device according to any one of claims 1 to 9, further comprising:
a light-emitting element layer provided on the thin film transistor layer, and
a sealing film provided to cover the light-emitting element layer.

11. The display device according to claim 10,
wherein the light-emitting element layer is an organic electroluminescence element layer.

12. A method for manufacturing a display device, the display device including a base substrate and a thin film transistor layer provided on the base substrate and including a semiconductor film, an inorganic insulating film, and a metal film layered in this order,
the thin film transistor layer including
a plurality of signal wiring lines formed of the metal film and provided to extend in parallel to each other in one direction,
a plurality of thin film transistors provided corresponding to a plurality of subpixels constituting a display region along each of the signal wiring lines, and
at least one lightning conductor element provided near the plurality of thin film transistors along each of the signal wiring lines,
each of the thin film transistors including a first semiconductor layer formed of the semiconductor film and provided in an island shape in such a manner as to overlap at least part of each of the signal wiring lines in a plan view, each of the lightning conductor elements including a second semiconductor layer formed of the semiconductor film and provided in an island shape in such a manner as to overlap at least part of each of the signal wiring lines in a plan view, the method comprising:
forming a thin film transistor layer in which the thin film transistor layer is formed on the base substrate, the forming a thin film transistor layer including
forming a semiconductor layer in which the first semiconductor layer and the second semiconductor layer are formed by, after forming the semiconductor film on a substrate surface where a lower layer of the semiconductor film is formed, patterning the semiconductor film,
forming an inorganic insulating film in which the inorganic insulating film is formed on the substrate surface where the first semiconductor layer and the second semiconductor layer are formed in such a manner as to cover the first semiconductor layer and the second semiconductor layer, and
forming a wiring line layer in which the plurality of signal wiring lines are formed by, after forming the metal film on the substrate surface where the inorganic insulating film is formed, patterning the metal film,
wherein in the forming a semiconductor layer, by controlling a photoresist contact angle and/or an etching condition of the semiconductor film, an angle of an end face of the second semiconductor layer with respect to an upper face of the base substrate is made larger than an angle of an end face of the first semiconductor layer with respect to the upper face of the base substrate in a cross-sectional view.
